(19) United States
(12) Patent Application Publication
(10) Pub. No.: US 2016/0093779 A1
(43) Pub. Date: Mar. 31, 2016

(54) LIGHT EMITTING DEVICE

(71) Applicant: Koito Manufacturing Co., Ltd., Tokyo (JP)

(72) Inventors: Yuzo Maeno, Shizuoka-shi (Shizuoka) (JP); Hisayoshi Daicho, Shizuoka-shi (Shizuoka) (JP); Yu Shinomiya, Shizuoka-shi (Shizuoka) (JP)

(21) Appl. No.: 14/855,713

(22) Filed: Sep. 16, 2015

(30) Foreign Application Priority Data
Sep. 25, 2014 (JP) 2014-195595

(51) Int. Cl. H01L 33/60; H01L 33/50

(52) U.S. Cl. CPC H01L 33/60; H01L 33/505; H01L 2933/0091

(57) ABSTRACT

Provided is a light emitting device. A semiconductor light emitting element with a peak wavelength ranging from 395 nm to 410 nm is used as a light source, light scattering particles made of a material with a band gap of 3.4 eV or more are dispersed in a dispersion medium of a reflection member, and a refractive index of the light scattering particles is larger than a refractive index of the dispersion medium by 0.3 or more. The semiconductor light emitting element has a 1 percentile value ranging from 365 nm to 383 nm in emission integrated intensity.

### CROSS-REFERENCE TO RELATED APPLICATIONS

This application is based on and claims priority from Japanese Patent Application No. 2014-195595, filed on Sep. 25, 2014, with the Japan Patent Office, the disclosure of which is incorporated herein in its entirety by reference.

### TECHNICAL FIELD

The present disclosure relates to a light emitting device, and particularly to a light emitting device including a light emitting diode that emits a short-wavelength visible light and a reflection member.

### BACKGROUND

A technology of a white light emitting device which uses a semiconductor light emitting element such as, for example, a light emitting diode (LED) or a laser diode (LD: semiconductor laser), as a light source, has recently rapidly developed. Such a light emitting device has also been used in applications requiring a large light quantity, such as, for example, a vehicle head lamp or an indoor/outdoor lighting device. Especially, in an application for the vehicle head lamp, it is important to use an LED light source close to a point light source as for a conventional halogen bulb or a discharge lamp, and it is required to further increase the brightness of the LED light source.

As a method of increasing the brightness of a white light emitting device using an LED, there is suggested a method of disposing a wavelength conversion material on the top surface of a blue LED chip, and covering side surfaces of the blue LED chip and the wavelength conversion material with a white reflection member containing light scattering particles in a resin (Japanese Patent Laid-Open Publication No. 2013-219397). Also, there is suggested a technology in which a wavelength conversion material and a translucent plate are disposed on a semiconductor light emitting element, the semiconductor light emitting element is surrounded by a white resin reflection member that contains metal oxide fine particles as filler, and a translucent member is disposed so as to be in contact with a side surface of the translucent plate to seal the reflection member (Japanese Patent Laid-Open Publication No. 2013-149906).

There is also suggested a method of using, as a semiconductor light emitting element, an LED chip that emits a short-wavelength visible light having a light emission peak wavelength in a range of 350 nm to 430 nm, and using, as a wavelength conversion material, a fluorescent material that is excited by the short-wavelength visible light and emits a yellow light having a peak wavelength in a range of 560 nm to 590 nm, and a fluorescent material that is excited by the short-wavelength visible light and emits a blue light having a peak wavelength in a range of 440 nm to 470 nm (Japanese Patent No. 4999783).

### SUMMARY

In the conventional technology disclosed in, for example, Japanese Patent Laid-Open Publication Nos. 2013-219397 and 2013-149906, since the periphery of a semiconductor light emitting element is surrounded by a white resin, a light emitted from the semiconductor light emitting element may be effectively reflected on a wavelength conversion member with a small volume, and its wavelength may be efficiently converted by the wavelength conversion member to obtain a white light. Thus, a high brightness is achieved. In such a conventional technology, an LED chip emitting a blue light is used as a semiconductor light emitting element, a part of the blue light is converted into a yellow light by a wavelength conversion member, and a white color is obtained by a mixed color of the blue light and the yellow light. Thus, a color temperature of the obtained white light tends to increase, and it is difficult to improve the color temperature.

In the conventional technology of Japanese Patent No. 4999783, by using a short-wavelength visible light as for a light source, a white light may be obtained by a mixed color of a blue light and a yellow light from fluorescent materials contained in a wavelength conversion material. Also, since the short-wavelength visible light from the light source has a low visibility, it is possible to improve the color temperature of a white light emitting device.

However, in the conventional technology of Japanese Patent No. 4999783, when a white resin is used in a reflection member to achieve the high brightness, even though light scattering particles suitable for reflecting a blue light are used as in Japanese Patent Laid-Open Publication Nos. 2013-219397 and 2013-149906, a good reflection characteristic is not always obtained and there is a limitation in achieving a high brightness because light sources are short-wavelength visible lights having different wavelengths.

Accordingly, the present disclosure has been made in consideration of the conventional problems described above, and an object of the present disclosure is to provide a light emitting device capable of improving a color temperature of a white light by using a semiconductor light emitting element emitting a short-wavelength visible light as a light source, as well as achieving a high brightness without reducing a light flux by using a reflection member having a satisfactory reflection characteristic.

In order to solve the problem described above, the light emitting device of the present disclosure includes a semiconductor light emitting element having a peak wavelength ranging from 395 nm to 410 nm; and a reflection member including light scattering particles dispersed in a dispersion medium. The light scattering particles are made of a material having a band gap of 3.4 eV or more, and a refractive index of the light scattering particles is larger than a refractive index of the dispersion medium by 0.3 or more.

In the light emitting device of the present disclosure, the semiconductor light emitting element emits a short-wavelength visible light with a peak wavelength ranging from 395 nm to 410 nm, while a band gap of the light scattering particles is 3.4 eV or more, and a refractive index difference between a dispersion medium and the light scattering particles is 0.3 or more so that the quantity of a light absorbed by light scattering particles may be suppressed and the light may be satisfactorily scattered by the light scattering particles, thereby improving the reflectivity of a reflection member. Accordingly, the semiconductor light emitting element emitting a short-wavelength visible light is used as a light source so as to improve a color temperature of a white light, while it is possible to achieve a high brightness without reducing a light flux by using a reflection member having a satisfactory reflection characteristic.

In the light emitting device of the present disclosure, the semiconductor light emitting element has a 1 percentile value ranging from 365 nm to 383 nm in emission integrated intensity.

As described above, when the semiconductor light emitting element that has a 1 percentile value ranging from 365 nm to 383 nm in the emission integrated intensity is used, a ratio of the quantity of the light absorbed by the light scattering particles constituted by a material having a band gap of 3.4 eV or more may be 1% or less based on the total quantity. Accordingly, the quantity of the light absorbed by the light scattering particles, with respect to the total quantity of the light emitted from the semiconductor light emitting element, may be reduced to some extent that is practically ignorable. Thus, it is possible to achieve a high brightness while suppressing the reduction of the light flux.

In the light emitting device of the present disclosure, the reflection member surrounds a periphery of the semiconductor light emitting element and is formed in a width ranging from 0.2 mm to 2.0 mm.

As described above, since the periphery of the semiconductor light emitting element is surrounded by the reflection member, the short-wavelength visible light from the semiconductor light emitting element may be suppressed from being leaked through the reflection member. Accordingly, it is possible to sufficiently reflect the short-wavelength visible light by the reflection member, and to achieve a high brightness while suppressing the reduction of the light flux.

The light emitting device of the present disclosure further includes a wavelength conversion member that is excited by a light from the semiconductor light emitting element to emit a light with a different wavelength. The wavelength conversion member is formed on the semiconductor light emitting element in a thickness ranging from 50 nm to 500 nm, and the reflection member is formed on at least a part of the periphery of the semiconductor light emitting element and the wavelength conversion member.

As described above, since the wavelength conversion member is formed on the semiconductor light emitting element, and the reflection member is formed on at least a part of the periphery of the wavelength conversion member, it is possible to effectively reflect the short-wavelength visible light on the wavelength conversion member by the reflection member. Accordingly, the wavelength of the short-wavelength visible light may be properly converted by the wavelength conversion member. Also, it is possible to achieve a high brightness while suppressing the reduction of the light flux.

In the light emitting device of the present disclosure, the light scattering particles are made of at least one of Nb₂O₅ and Ta₂O₅.

As described above, since an optimum material is selected as the light scattering particles in order to reflect the short-wavelength visible light, the absorption of the short-wavelength visible light in the light scattering particles may be suppressed, and the refractive index difference with respect to the dispersion medium may be secured, thereby improving the reflectivity of the reflection member. Accordingly, the reflectivity of the reflection member may be improved, and also it is possible to achieve a high brightness while suppressing the reduction of the light flux.

In the present disclosure, it is possible to provide a light emitting device capable of improving a color temperature of a white light by using a semiconductor light emitting element emitting a short-wavelength visible light as a light source, as well as achieving a high brightness without reducing a light flux by using a reflection member having a satisfactory reflection characteristic.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIGS. 1A and 1B are a schematic plan view and a schematic sectional view illustrating a light emitting device according to a first exemplary embodiment.

FIG. 2 is a graph illustrating an emission integrated intensity of light emitted from a semiconductor light emitting element.

FIG. 3 is a spectrum diagram illustrating light emission characteristics measured on a light emitting device in each of Example 1 and Comparative Examples 1 and 2.

FIG. 4 is a schematic sectional view illustrating a light emitting device according to a second exemplary embodiment.

FIG. 5 is a schematic sectional view illustrating a light emitting device according to a third exemplary embodiment.

FIG. 6 is a schematic sectional view illustrating a light emitting device according to a fourth exemplary embodiment.

FIG. 7 is a schematic sectional view illustrating a light emitting device according to a fifth exemplary embodiment.

FIG. 8 is a schematic sectional view illustrating a light emitting device according to a sixth exemplary embodiment.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made, without departing from the spirit or scope of the subject matter presented here.

Hereinafter, exemplary embodiments of the present disclosure will be described in detail with reference to drawings. The same or equivalent components, members and processes illustrated in the drawings will be denoted by the same reference numerals and the duplicative descriptions thereof will be properly omitted.

### First Exemplary Embodiment

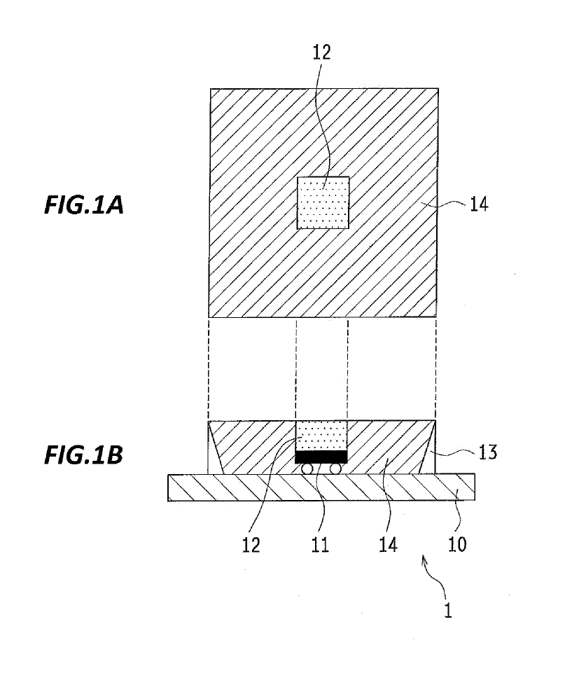

FIGS. 1A and 1B are schematic views illustrating a light emitting device 1 according to a first exemplary embodiment. FIG. 1A is a schematic plan view and FIG. 1B is a schematic sectional view. In the light emitting device 1 illustrated in FIGS. 1A and 1B, a semiconductor light emitting element 11 is mounted on a substrate 10, and a wavelength conversion member 12 is provided on the semiconductor light emitting element 11. A dam member 13 is disposed on the substrate 10 to surround the periphery of the semiconductor light emitting element 11 and the wavelength conversion member 12, and a reflection member 14 is filled inside the dam member 13.

The substrate 10 is a flat panel-like member configured to mount another member to be supported thereon, and may be formed of either an insulating material or a conductive material. The substrate 10 may be formed of a high thermal-conductivity material. For example, a ceramic substrate, a glass epoxy substrate, a flexible substrate, a composite substrate having an insulating film formed on a metal substrate, or a substrate having a lead frame fixed thereto by an insulating material may be used. Although omitted in FIGS. 1A and 1B, on a surface of the substrate 10, on which the semiconductor light emitting element 11 is mounted, a wiring layer made of, for example, a metal material, is formed, and is connected to the semiconductor light emitting element 11 so as to supply a current.

The semiconductor light emitting element 11 is a light emitting diode (LED) that emits a short-wavelength visible light. The short-wavelength visible light in the present disclosure refers to a light having a wavelength around 400 nm which is shorter than that of a blue light, more specifically a light having a light emission peak wavelength in a wavelength range of 395 nm to 410 nm. The short-wavelength visible light in this range has a lower visibility than a light around 450 nm, that is, a blue light. Thus, the short-wavelength visible light has a characteristic in that even if a light quantity is increased, an effect on a color temperature of a white light in its entirety is small.

The semiconductor light emitting element 11 may include an InGaN-based compound semiconductor as an active layer. The InGaN-based compound semiconductor has an emission wavelength that varies depending on the content of In. When the content of In is large, the emission wavelength tends to be a long wavelength, while when the content is small, the emission wavelength tends to be a short wavelength. It has been found that when an InGaN-based active layer has a composition ratio of the content of In such that the peak wavelength becomes about 400 nm, the quantum efficiency is highest. Accordingly, when the semiconductor light emitting element 11 is formed of an InGaN-based compound semiconductor material, the luminous efficiency of the short-wavelength visible light may be optimized. However, a material that forms the semiconductor light emitting element 11 is not limited to the InGaN-based material, but another material may be employed as long as it is capable of emitting a short-wavelength visible light. For example, a Group II-VI compound semiconductor, a ZnO-based compound semiconductor, or a Ga₂O₃-based compound semiconductor may be employed.

The wavelength conversion member 12 is a member that converts the wavelength of a part of the short-wavelength visible light emitted from the semiconductor light emitting element 11 into another wavelength. In FIGS. 1A and 1B, a phosphor-containing sheet formed in a sheet form, which is obtained by dispersing fine particles of a fluorescent material in a resin, is fixed to the top surface of the semiconductor light emitting element 11 through an adhesive (not illustrated). The wavelength conversion member 12 is not limited to the phosphor-containing sheet as long as it is a member that is capable of converting the wavelength of the short-wavelength visible light. A resin having fluorescent fine particles dispersed therein may be applied. Otherwise, for example, a fluorescent material-containing glass or a fluorescent ceramic plate may be used. As the resin in which fluorescent particles are dispersed, for example, a dimethyl silicon resin or an epoxy resin may be used.

The wavelength conversion member 12 includes a fluorescent material that is excited by the short-wavelength visible light and emits a blue light, and a fluorescent material that is excited by the short-wavelength visible light and emits a yellow light. As the fluorescent material that emits a blue light, for example, (Ca,Sr)₅(PO₄)₃Cl:Eu may be used, and as the fluorescent material that emits a yellow light, for example, (Ca,Sr)₇(SiO₃)₆Cl₂:Eu may be used. However, other materials may be employed. The fluorescent materials included in the wavelength conversion member are not limited to the materials that emit a blue light and a yellow light, but materials emitting other colors may be employed as long as a white color can be obtained through color mixing. For example, materials which emit a red light, a blue light and a green light may be included, respectively. Also, a fluorescent material that emits another color may be added to adjust a color temperature.

The dam member 13 is a frame that is arranged on the substrate 10 at a position spaced apart from the semiconductor light emitting element 11 to surround the periphery of the semiconductor light emitting element 11. The dam member 13 may be employed in various aspects. For example, a resin or ceramic material molded into a frame shape may be fixed on the substrate 10 through an adhesive, or a material such as, for example, a resin, may be applied and cured in a frame shape on the substrate 10. As illustrated in FIGS. 1A and 1B, the dam member 13 is formed to have a greater height than the semiconductor light emitting element 11, and have almost the same height as the wavelength conversion member 12 arranged on the semiconductor light emitting element 11.

The reflection member 14 is obtained by dispersing light scattering particles in a dispersion medium such as, for example, a resin. The reflection member 14 is configured to reflect a short-wavelength visible light from the semiconductor light emitting element 11 and a visible light from the wavelength conversion member 12. As the dispersion medium, a material that transmits the short-wavelength visible light may be employed. For example, a dimethyl silicon resin or an epoxy resin, or a glass may be used. As illustrated in FIGS. 1A and 1B, the reflection member 14 is filled inside the dam member 13 and formed to cover the side surfaces of the semiconductor light emitting element 11 and the wavelength conversion member 12. In FIGS. 1A and 1B, the reflection member 14 is formed to have almost the same height as the wavelength conversion member 12 and the dam member 13.

The ratio of the dispersion medium to the light scattering particles in the reflection member 14 may be in a range in which the concentration of the light scattering particles ranges from 10 vol % to 20 vol %. When the concentration of the light scattering particles is less than 10 vol %, the density of the light scattering particles is decreased so that the short-wavelength visible light is not sufficiently reflected by the reflection member 14, resulting in light leakage. Also, when the concentration is greater than 20 vol %, the light scattering particles may not be sufficiently wetted in the dispersion medium so that voids may easily occur and the yield is lowered. Thus, this is not desirable. When the voids occur, the short-wavelength visible light may be leaked via the voids. Thus, the short-wavelength visible light may not be sufficiently reflected by the reflection member 14.

In the particle diameter of the light scattering particles, the median of the particle diameter distribution may be in a range of 0.1 μm≦50% D≦10 μm. More specifically, the median of the particle diameter distribution may be in a range of 0.1 μm≦50% D≦3 μm. When the particle diameter is less than the range, it is difficult for the light scattering particles to be uniformly dispersed in the dispersion medium. When the particle diameter is greater than the range, the specific surface area of the light scattering particles becomes small so that it is difficult for the short-wavelength visible light to be scattered.

The width of the reflection member 14 (the horizontal thickness in the drawing) may range from 0.2 mm to 2.0 mm More specifically, the width of the reflection member 14 may range from 0.5 mm to 1.5 mm. When the width of the reflection member 14 is smaller than this range, a leaked light that is extracted to the outside through the reflection member 14 is increased so that the short-wavelength visible light may not be sufficiently reflected on the wavelength conversion member 12. When the short-wavelength visible light is not sufficiently reflected on the wavelength conversion member 12, the quantity of the blue light and the yellow light which are to be subjected to wavelength conversion so as to obtain the white light is insufficient. As a result, the light flux of the white light is reduced, thereby reducing the brightness. When the width of the reflection member 14 is larger than this range, the moldability of the reflection member 14 is degraded.

When a current is supplied to the light emitting device 1, the semiconductor light emitting element 11 emits a short-wavelength visible light having a light emission peak wavelength around 400 nm. When the short-wavelength visible light from the semiconductor light emitting element 11 is incident on fluorescent materials included in the wavelength conversion member 12, the fluorescent materials are excited to emit a blue light and a yellow light, and then a white light obtained through color mixing is extracted to the outside of the light emitting device 1.

When the short-wavelength visible light from the semiconductor light emitting element 11 and the light from the wavelength conversion member 12 are incident on the reflection member 14, the light is refracted due to a refractive index difference between the dispersion medium of the reflection member 14 and light scattering particles dispersed therein, and is scattered by a change in a traveling direction. Since many light scattering particles are dispersed in the reflection member 14, the light that has been repeatedly scattered by many light scattering particles is extracted again to the outside of the reflection member 14. Accordingly, the light incident on the reflection member 14 is scattered and reflected so that a part of the light is extracted to the outside of the light emitting device 1 through the reflection member 14 and another part is incident on the wavelength conversion member 12 side to be subjected to a wavelength conversion.

In the light emitting device 1, the semiconductor light emitting element 11 emitting a short-wavelength visible light having a low visibility is used. Thus, when the short-wavelength visible light that is directly extracted to the outside is increased, the quantity of the light that is subjected to the wavelength conversion by the wavelength conversion member 12 is decreased so that the light flux of the white light is reduced. Accordingly, it becomes important to select a dispersion medium and light scattering particles which may satisfactorily reflect the short-wavelength visible light on the wavelength conversion member 12.

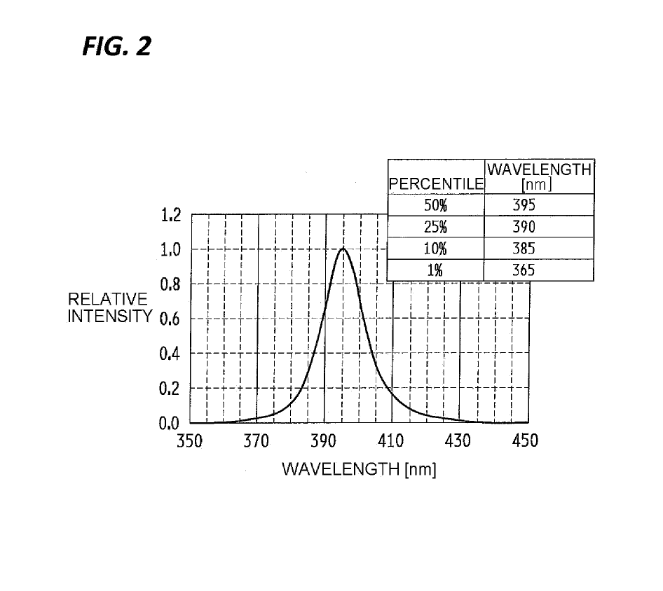

FIG. 2 is a graph illustrating an emission integrated intensity of light emitted from the semiconductor light emitting element 11. FIG. 2 illustrates a case where the light emission peak wavelength is present at the shortest wavelength of 395 nm in the wavelength range of the short-wavelength visible light, from 395 nm to 410 nm. As illustrated in FIG. 2, the distribution of the emission spectrum of the semiconductor light emitting element 11 approximates to a Gaussian distribution with a half width of about 30 nm and expands from about 350 nm to 450 nm. In such a semiconductor light emitting element 11, when the emission intensity is integrated from the short-wavelength side with respect to the integration value of the emission intensity of the entire wavelength range, a wavelength at the 1 percentile is 365 nm, a wavelength at the 10 percentile is 385 nm, a wavelength at the 25 percentile is 390 nm, and a wavelength at the 50 percentile is 395 nm. When the semiconductor light emitting element 11 having a light emission peak wavelength of 410 nm was used, the 1 percentile value was 383 nm.

As clearly found in FIG. 2, when the semiconductor light emitting element 11 emitting the short-wavelength visible light is used, wavelengths of 380 nm or less are included at about several % in the emission intensity distribution. In a blue LED that has been used in a conventional light emitting device, unlike that in the emission integrated intensity illustrated in FIG. 2, the peak wavelength is shifted to about 450 nm. Accordingly, even if the half width was almost the same as that of the present disclosure, in the blue LED, the spectrum was not expanded to a region of 380 nm or less, and the blue light was hardly absorbed even by using particles such as TiO₂ as light scattering particles.

However, in the light emitting device 1 of the present disclosure, since the semiconductor light emitting element 11 emitting a short-wavelength visible light is used, a part of the short-wavelength visible light is absorbed by light scattering particles if the light scattering particles dispersed in the dispersion medium of the reflection member 14 are not properly selected. As a result, the quantity of the short-wavelength visible light incident on the wavelength conversion member 12 is decreased, and the blue light and the yellow light which are to be subjected to the wavelength conversion by the wavelength conversion member 12 are also decreased, so that the light flux and brightness of the light emitting device 1 are reduced. Such a problem has not occurred in a conventional technology in which a blue LED is used as a semiconductor light emitting element.

It is assumed that light absorption by the light scattering particles is mainly caused by a band gap of the material that constitutes the light scattering particles, and a wavelength of the light. Each material that constitutes the light scattering particles has its own band gap, and absorbs a light having a wavelength shorter than its band gap wavelength which is converted from the band gap energy in terms of the wavelength. Accordingly, in order to ensure that the short-wavelength visible light having a spectrum distribution illustrated in FIG. 2 is hardly absorbed, it is needed to use a material having a band gap wavelength that does not overlap the spectrum distribution of the short-wavelength visible light as far as possible, as light scattering particles.

Specifically, in the emission integrated intensity of the semiconductor light emitting element 11, a material having a band gap wavelength shorter than a wavelength at the 1 percentile value is selected as for the material for light scattering particles. When such a band gap wavelength is selected, a ratio of a light absorbed by the light scattering particles, with respect to a light emitted from the semiconductor light emitting element 11, may be 1% or less, and the reduction of the light flux by light absorption may be practically ignored. As illustrated in FIG. 2, in a case of the short-wavelength visible light having a light emission peak wavelength of 395 nm, the 1 percentile value is 365 nm, and in a case of the short-wavelength visible light having a light emission peak wavelength of 410 nm, the 1 percentile value is 383 nm. Accordingly, when a material having a band gap wavelength of 365 nm or less (3.4 eV or more) is selected, the short-wavelength visible light is suppressed from being absorbed by the light scattering particles. Thus, it is possible to achieve a high brightness without reducing the light flux of the light emitting device 1.

Also, in order to satisfactorily reflect the short-wavelength visible light by the reflection member 14, a refractive index difference between a dispersion medium and light scattering particles also becomes an important factor. As described above, in the reflection member 14, light scattering caused by the refractive index difference between the dispersion medium and the light scattering particles is repeated, while the short-wavelength visible light is extracted again in its incident direction such that the short-wavelength visible light is scattered and reflected. Here, when the refractive index difference between the dispersion medium and the light scattering particles is small, an angle at which the light is scattered is decreased such that the light is not sufficiently scattered. Thus, the total quantity of the light that is leaked to the outside through the reflection member 14 is increased. Specifically, it is desirable that the refractive index of the light scattering particles is larger than that of the dispersion medium by 0.3 or more.

### Example

In Example of a first exemplary embodiment of the present disclosure, a light emitting device 1 illustrated in FIGS. 1A and 1B was manufactured. As the substrate 10, a ceramic substrate made of MN was used, and as the semiconductor light emitting element 11, an LED chip having an active layer made of an InGaN-based material and a light emission peak wavelength of 400 nm was used. The LED chip had a size of 1 mm×1 mm, and was flip-chip mounted on the substrate 10.

As the fluorescent particles to be contained in the wavelength conversion member 12, a blue phosphor, (Ca,Sr)₅(PO₄)₃Cl:Eu, and a yellow phosphor, (Ca,Sr)₇(SiO₃)₆Cl₂:Eu, were used and were mixed at a ratio at which the color temperature becomes 5500 K. The two kinds of mixed fluorescent particles were dispersed in a dimethyl silicon resin with a refractive index of 1.4 such that the concentration becomes 15 vol %, and were molded in a sheet form with a thickness of 300 μm. The obtained phosphor-containing sheet was cut into a size of 1.2 mm×1.2 mm, and was fixed at positions where it protrudes from four sides of the LED chip by 0.1 mm through a translucent adhesive resin.

The frame-shaped dam member 13 configured to surround the position spaced apart from the wavelength conversion member 12 by 1 mm was formed and was provided on the substrate 10. Accordingly, the width of the reflection member 14 formed inside the dam member 13 becomes 1 mm.

The reflection member 14 obtained by dispersing light scattering particles made of each of materials noted in [Table 1] in a dimethyl silicon resin with a refractive index of 1.4 was filled inside the dam member 13 through dispense-coating so as to cover the side surfaces of the semiconductor light emitting element 11 and the wavelength conversion member 12. Thus, the light emitting devices 1 of Examples 1 to 9 and Comparative Examples 1 to 5 were obtained. In each of materials in Examples 1 to 9 and Comparative Examples 2 to 5, the concentration of light scattering particles in the dimethyl silicon resin was adjusted to range from 10 vol % to 20 vol %, and the particle diameter was adjusted to fall within a range of 0.1 μm≦50% D≦3 μm. In Comparative Example 1, the reflection member 14 was formed by only the dimethyl silicon resin having a refractive index of 1.4, which is not added with light scattering particles.

On each of the light emitting devices 1 obtained as described above, a brightness and a light flux were measured by fixing an operation current to be supplied to the light emitting device 1 to 350 mA. In the measurement method of the brightness, after a lapse of 20 min to 30 min from the supply of the operation current, imaging by a camera was performed with a focus on the top surface of the wavelength conversion member 12 in a dark room, and then the brightness was calculated by measuring the light quantity. In the measurement method of the light flux, the light emitting device 1 was provided in an integrating sphere, and the operation current was supplied for 10 msec so as to measure the light flux. On the brightness and the light flux measured as described above, a relative brightness and a relative light flux were calculated based on Comparative Example 1.

In Table 1, in each of materials in Examples 1 to 9 and Comparative Examples 1 to 5, a band gap, a refractive index, a relative brightness, and a relative light flux are noted.

TABLE 1

| | Light | | | | Relative |
|---|---|---|---|---|---|
| | Scattering | | Refractive | Relative | Light |
| | Particles | Band Gap | Index | Brightness | Flux |
| Example 1 | Ga₂O₃ | 4.8 | 1.92 | 1.35 | 1.06 |
| Example 2 | HfO₂ | 6.0 | 1.95 | 1.37 | 1.08 |
| Example 3 | Y₂O₃ | 3.8 | 1.87 | 1.35 | 1.05 |
| Example 4 | ZnO | 3.4 | 1.95 | 1.34 | 1.06 |
| Example 5 | Nb₂O₅ | 3.4 | 2.33 | 1.40 | 1.11 |
| Example 6 | Ta₂O₅ | 4.0 | 2.16 | 1.38 | 1.13 |
| Example 7 | ZrO₂ | 5.0 | 2.03 | 1.35 | 1.10 |
| Example 8 | AlN | 6.0 | 1.9-2.2 | 1.30 | 1.09 |
| Example 9 | BN | 6.0 | 2.17 | 1.38 | 1.14 |
| Comparative | — | — | — | 1.00 | 1.00 |
| Example 1 | | | | | |
| Comparative | TiO₂(rutile) | 3.0 | 2.72 | 1.19 | 1.01 |
| Example 2 | | | | | |
| Comparative | MgF₂ | 5.0 | 1.37 | 1.01 | 0.95 |
| Example 3 | | | | | |
| Comparative | Al₂O₃ | 6.0 | 1.63 | 1.03 | 1.02 |
| Example 4 | | | | | |
| Comparative | SiO₂ | 9.0 | 1.45 | 1.03 | 0.96 |
| Example 5 | | | | | |

In Examples 1 to 9, each of Ga₂O₃, HfO₂, Y₂O₃, ZnO, Nb₂O₅, Ta₂O₅, ZrO₂, MN, and BN has a band gap of 3.4 eV or more, and a refractive index difference between each material and a dimethyl silicon resin as a dispersion medium is 0.3 or more. In Examples 1 to 9, a relative brightness is 1.3 or more, and a relative light flux is also 1.05 or more, so that not only the light flux is improved but also the brightness is improved.

As noted in Table 1, in rutile-type TiO₂ of Comparative Example 2, since a refractive index difference with respect to a dimethyl silicon resin is large, the quantity of a light reflected from the reflection member 14 toward the wavelength conversion member 12 may be secured, but about several % of the short-wavelength visible light is absorbed due to a small band gap. Accordingly, a relative brightness and a relative light flux were reduced as compared to that in Examples 1 to 9.

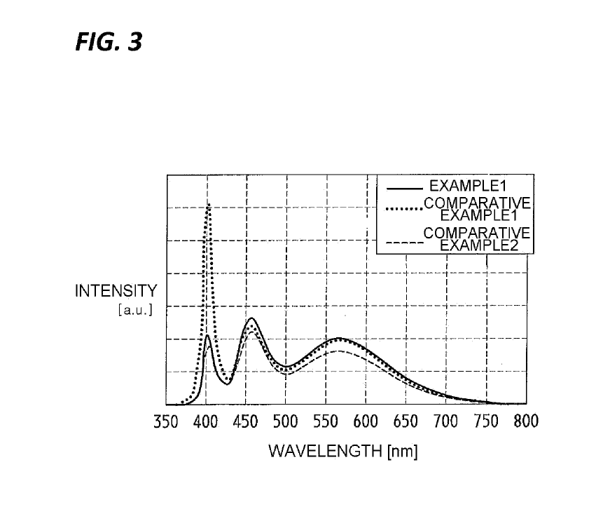

The partial absorption of the short-wavelength visible light by light scattering particles in Comparative Example 2 will be described using FIG. 3. FIG. 3 is a spectrum diagram illustrating light emission characteristics measured on the light emitting device 1 in each of Example 1 and Comparative Examples 1 and 2. In the drawing, the solid line represents a spectrum of Example 1, the dotted line represents a spectrum of Comparative Example 1, and the broken line represents a spectrum of Comparative Example 2. In Comparative Example 1, light scattering particles are not dispersed in a dimethyl silicon resin, and the majority of the light from the semiconductor light emitting element 11 passes through the reflection member 14. Thus, the short-wavelength visible light emitted from the LED chip has a maximum intensity at a wavelength of 400 nm. In Comparative Example 2, since a band gap has a small value of 3.0 eV, it is found that the light was absorbed in a wavelength range around the short-wavelength visible light, and the light intensity became smaller than that of Example 1.

Each of MgF₂, Al₂O₃, and SiO₂ in Comparative Examples 3 to 5 has a band gap sufficiently larger than 3.4 eV, and thus a reduction of a light quantity by the absorption of the short-wavelength visible light in the light scattering particles is hardly seen. However, in each of Comparative Examples 3 to 5, since the refractive index difference with respect to the dimethyl silicon resin as a dispersion medium is less than 0.3, the short-wavelength visible light is not sufficiently scattered by the light scattering particles in the reflection member 14, and is not sufficiently reflected on the wavelength conversion member 12. Accordingly, a relative brightness and a relative light flux became smaller than those in Examples 1 to 9.

Among Examples 1 to 9, each of Examples 5 to 7, and 9 employing Nb₂O₅, Ta₂O₅, ZrO₂, and BN has a particularly large relative brightness and a particularly large relative light flux. However, ZrO₂ and BN are slightly colored, thereby absorbing a part of a visible light. Thus, Nb₂O₅ and Ta₂O₅ in Examples 5 and 6 are most preferable as the light scattering particles.

As noted in Table 1, it can be found that only the selection of light scattering particles that satisfy any one of a refractive index difference with respect to the dispersion medium and a band gap value is not sufficient in order to satisfactorily reflect a short-wavelength visible light by the reflection member 14 and to increase the light flux and the brightness of a white light emitted from the light emitting device 1. This has not caused a problem in a conventional light emitting device employing a blue LED chip, but is a characteristic phenomenon in a light emitting device employing the semiconductor light emitting element 11 that emits a short-wavelength visible light. The improvement effect of a light flux and a brightness may be obtained only when three conditions are satisfied. The three conditions are as follows: a semiconductor light emitting element has a peak wavelength ranging from 395 nm to 410 nm, light scattering particles have a band gap of 3.4 eV or more, and a refractive index of the light scattering particles is larger than that of a dispersion medium by 0.3 or more.

Then, Examples 10 to 12 and Comparative Examples 6 and 7 were manufactured in which as for light scattering particles, Ta₂O₅ was used, and the thickness of the wavelength conversion member 12 and the concentration of fluorescent particles were varied. Here, a thickness was determined as a phosphor condition of the wavelength conversion member 12, and the amount of the fluorescent particles that may achieve a color temperature of 5500 K at the determined thickness was determined. Then, the particles were dispersed in a dimethyl silicon resin. Accordingly, there is a tendency that the concentration (vol %) of the fluorescent particles is decreased according to an increase of the thickness of the wavelength conversion member 12. In each of Examples 10 to 12 and Comparative Examples 6 and 7, the light emitting device 1 was manufactured in the same manner as that in Example 6 except a thickness and a concentration of a wavelength conversion member. In the reflection member 14, the concentration of Ta₂O₅ as light scattering particles was 15 vol %.

In Table 2, measurement results of a relative brightness and a relative light flux in each of Examples 10 to 12 and Comparative Examples 6 and 7 are noted, which were obtained in the same measurement method as that in Examples 1 to 9 and Comparative Examples 1 to 5. The relative brightness and the relative brightness are based on Comparative Example 1 noted in Table 1.

TABLE 2

| | Wavelength Conversion | | | |
|---|---|---|---|---|
| | Member Condition | | | |
| | Thickness | Concentration | Relative | Relative Light |
| | [μm] | [vol %] | Brightness | Flux |
| Example 10 | 80 | 32 | 1.40 | 1.03 |
| Example 11 | 200 | 15 | 1.37 | 1.08 |
| Example 12 | 450 | 6.7 | 1.30 | 1.01 |
| Comparative | 40 | 38 | 1.21 | 0.94 |
| Example 6 | | | | |
| Comparative | 600 | 5 | 1.14 | 0.99 |
| Example 7 | | | | |

As clearly seen from Table 2, in Examples 10 to 12, the thickness of the wavelength conversion member 12 is 80 μm, 200 μm, and 450 μm, respectively, and in all of Examples 10 to 12, the relative brightness is 1.3 or more, and the relative light flux is 1.00 or more so that not only the light flux is improved but also the brightness is improved. In contrast, in Comparative Examples 6 and 7, the thickness of the wavelength conversion member 12 is 40 μm and 600 μm, respectively, and in all of Comparative Examples 6 and 7, the relative brightness is less than 1.3, and the relative light flux is less than 1.00.

As in Comparative Example 6, when the thickness of the wavelength conversion member 12 is less than 50 μm, the concentration of fluorescent particles dispersed in a dimethyl silicon resin to achieve a desired color temperature is extremely increased, so that scattering and shielding of a light on fluorescent particle surfaces are increased, and the light extraction becomes difficult. Thus, the light flux and the brightness are lowered. Also, the excessively high concentration of the fluorescent particles is not desirable since the light scattering particles may not be sufficiently wetted in the dimethyl silicon resin as for the dispersion medium as described above so that voids may easily occur and the yield is lowered. When the voids occur, the short-wavelength visible light may be leaked via the voids. Thus, the short-wavelength visible light may not be sufficiently reflected by the reflection member 14.

When the thickness of the wavelength conversion member 12 is larger than 500 μm as in Comparative Example 7, the area of the side surface of the wavelength conversion member 12 covered with the reflection member 14 is extremely increased. Accordingly, the ratio of the light extraction surfaces of the wavelength conversion member 12 exposed from the top surface of the light emitting device 1 is reduced, and the light extracted from portions other than the light extraction surfaces is increased. As a result, the quantity of the light extracted from the light extraction surfaces is reduced, and thus, the light flux and the brightness of the light emitting device 1 are reduced. Accordingly, the thickness of the wavelength conversion member 12 may range from 50 μm to 500 μm.

In the light emitting device 1 of the present disclosure, the semiconductor light emitting element emits a short-wavelength visible light with a peak wavelength ranging from 395 nm to 410 nm, while a band gap of the light scattering particles is 3.4 eV or more, and a refractive index difference between a dispersion medium and the light scattering particles is 0.3 or more so that the quantity of a light absorbed by light scattering particles may be suppressed and the light may be satisfactorily scattered by the light scattering particles, thereby improving the reflectivity of a reflection member.

Also, when a semiconductor light emitting element that has the 1 percentile value ranging from 365 nm to 383 nm in the emission integrated intensity is used, the ratio of the quantity of the light absorbed by the light scattering particles constituted by a material having a band gap of 3.4 eV or more may be 1% or less based on the total quantity. Accordingly, the quantity of the light absorbed by the light scattering particles, with respect to the total quantity of the light emitted from the semiconductor light emitting element, may be reduced to some extent that is practically ignorable. Thus, it is possible to achieve a high brightness while suppressing the reduction of the light flux.

Accordingly, although the semiconductor light emitting element emitting a short-wavelength visible light is used as a light source so as to improve a color temperature of a white light, it is possible to achieve a high brightness without reducing the light flux by using a reflection member having a satisfactory reflection characteristic.

### Second Exemplary Embodiment

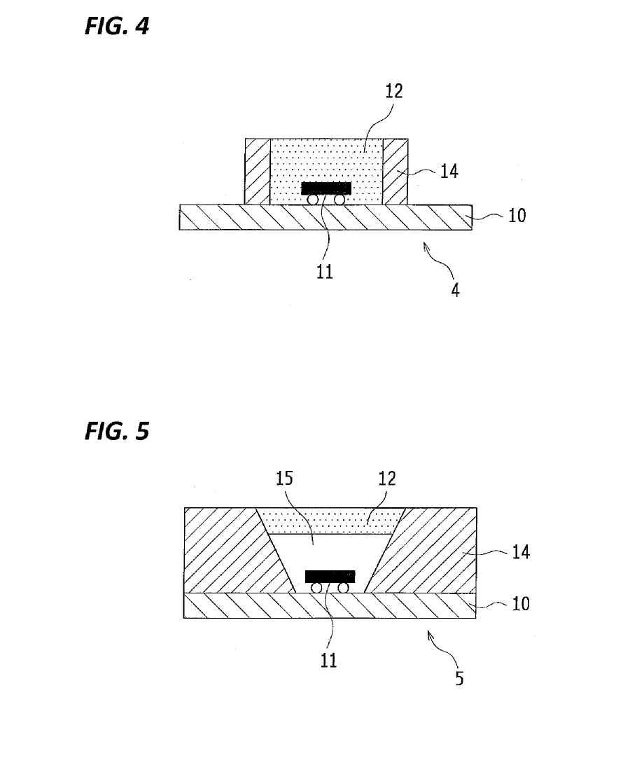

FIG. 4 is a schematic sectional view illustrating a light emitting device according to a second exemplary embodiment. As illustrated in FIG. 4, in a light emitting device 4 of the second exemplary embodiment, a semiconductor light emitting element 11 is mounted on a substrate 10, a reflection member 14 in a frame shape is disposed around the semiconductor light emitting element 11 to be spaced apart from the semiconductor light emitting element 11, and a wavelength conversion member 12 is filled inside the reflection member 14.

In the present exemplary embodiment, since the reflection member 14 is formed around the semiconductor light emitting element 11 to be spaced apart from the semiconductor light emitting element 11, the side surfaces and the top surface of the semiconductor light emitting element 11 are covered with the wavelength conversion member 12. Accordingly, a short-wavelength visible light emitted from the semiconductor light emitting element 11 is incident on the wavelength conversion member 12 and subjected to wavelength conversion. The short-wavelength visible light which is not subjected to the conversion by the wavelength conversion member 12 reaches the reflection member 14 and is scattered and reflected to be incident on the wavelength conversion member 12 again. Accordingly, it is possible to satisfactorily reflect the short-wavelength visible light by the reflection member 14 so that the efficiency of white light emission from the wavelength conversion member 12 may be improved, thereby improving the light flux and the brightness of the light emitting device 4.

### Third Exemplary Embodiment

FIG. 5 is a schematic sectional view illustrating a light emitting device according to a third exemplary embodiment. As illustrated in FIG. 5, in a light emitting device 5 of the third exemplary embodiment, a semiconductor light emitting element 11 is mounted on a substrate 10, a reflection member 14 in a frame shape, which has an inclined inner side surface, is disposed around the semiconductor light emitting element 11 to be spaced apart from the semiconductor light emitting element 11, and a translucent member 15 is filled inside the reflection member 14 to seal the semiconductor light emitting element 11. A wavelength conversion member 12 is formed on the reflection member 14.

The translucent member 15 is a transparent material that transmits a short-wavelength visible light emitted from the semiconductor light emitting element 11, and may be made of, for example, a silicon resin, an epoxy resin, or a glass. The translucent member 15 serves as a sealing member of the semiconductor light emitting element 11. The wavelength conversion member 12 may be separately prepared as a platy member, an inert gas, such as, for example, nitrogen, as the translucent member 15 may be filled therein, and the semiconductor light emitting element 11 may be airtightly sealed by the reflection member 14 and the wavelength conversion member 12.

In the present exemplary embodiment, the short-wavelength visible light emitted from the semiconductor light emitting element 11 reaches the wavelength conversion member 12 or the reflection member 14 through the translucent member 15. The short-wavelength visible light that has reached the reflection member 14 is scattered and reflected by the reflection member 14 to be incident on the wavelength conversion member 12. Accordingly, it is possible to satisfactorily reflect the short-wavelength visible light by the reflection member 14 so that the efficiency of white light emission from the wavelength conversion member 12 may be improved, thereby improving the light flux and the brightness of the light emitting device 5.

### Fourth Exemplary Embodiment

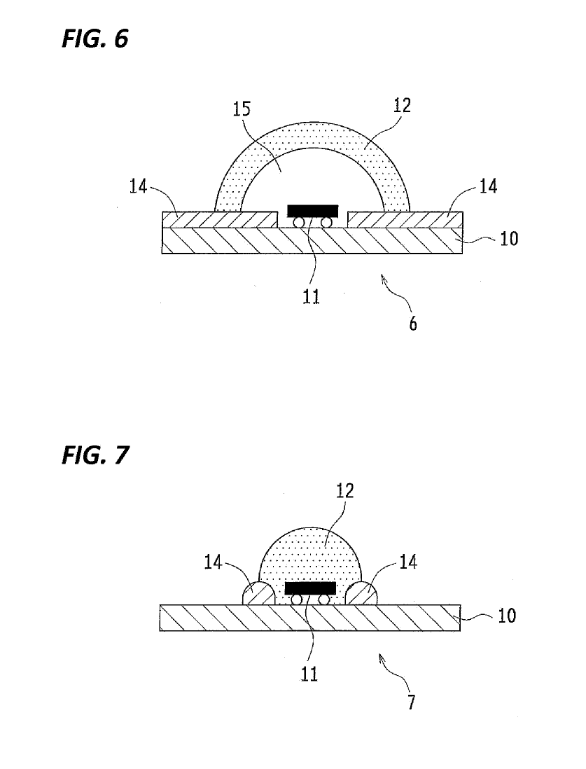

FIG. 6 is a schematic sectional view illustrating a light emitting device according to a fourth exemplary embodiment. As illustrated in FIG. 6, in a light emitting device 6 of the fourth exemplary embodiment, a semiconductor light emitting element 11 is mounted on a substrate 10, and a reflection member 14 is formed to cover the portion of the surface of the substrate 10 around the semiconductor light emitting element 11. Also, a translucent member 15 is formed in a hemispheric shape on the semiconductor light emitting element 11 and the reflection member 14 around the semiconductor light emitting element 11, and a wavelength conversion member 12 in a dome shape is formed outside the translucent member 15.

The translucent member 15 is a transparent material that transmits a short-wavelength visible light emitted from the semiconductor light emitting element 11, and may be made of, for example, a silicon resin, an epoxy resin, or a glass. The translucent member 15 serves as a sealing member of the semiconductor light emitting element 11. The wavelength conversion member 12 may be separately prepared as a platy member, an inert gas, such as, for example, nitrogen, as the translucent member 15 may be filled therein, and the semiconductor light emitting element 11 may be airtightly sealed by the reflection member 14 and the wavelength conversion member 12.

In the present exemplary embodiment, the short-wavelength visible light emitted upward from the semiconductor light emitting element 11 reaches the wavelength conversion member 12 through the translucent member 15. The short-wavelength visible light laterally emitted from the semiconductor light emitting element 11 reaches the reflection member 14, and is scattered and reflected to be incident on the wavelength conversion member 12. Accordingly, it is possible to satisfactorily reflect the short-wavelength visible light by the reflection member 14 so that the efficiency of white light emission from the wavelength conversion member 12 may be improved, thereby improving the light flux and the brightness of the light emitting device 6.

### Fifth Exemplary Embodiment

FIG. 7 is a schematic sectional view illustrating a light emitting device according to a fifth exemplary embodiment. As illustrated in FIG. 7, in a light emitting device 7 of the fifth exemplary embodiment, a semiconductor light emitting element 11 is mounted on a substrate 10, a reflection member 14 is disposed around the semiconductor light emitting element 11 to be spaced apart from the semiconductor light emitting element 11, and a wavelength conversion member 12 is dropped inside the reflection member 14 to be formed in substantially a hemispheric shape. Herein, the reflection member 14 serves as a dam member that blocks the wavelength conversion member 12 when the wavelength conversion member 12 is dropped so that the wavelength conversion member 12 is formed in substantially a hemispheric shape in the vicinity of the semiconductor light emitting element 11.

In the present exemplary embodiment, since the reflection member 14 is formed around the semiconductor light emitting element 11 to be spaced apart from the semiconductor light emitting element 11, the side surfaces and the top surface of the semiconductor light emitting element 11 are covered with the wavelength conversion member 12. Accordingly, a short-wavelength visible light emitted from the semiconductor light emitting element 11 is incident on the wavelength conversion member 12 and subjected to wavelength conversion. The short-wavelength visible light which is laterally emitted from the semiconductor light emitting element 11 but is not subjected to the conversion by the wavelength conversion member 12 reaches the reflection member 14 and is scattered and reflected to be incident on the wavelength conversion member 12 again. Accordingly, it is possible to satisfactorily reflect the short-wavelength visible light by the reflection member 14 so that the efficiency of white light emission from the wavelength conversion member 12 may be improved, thereby improving the light flux and the brightness of the light emitting device 7.

### Sixth Exemplary Embodiment

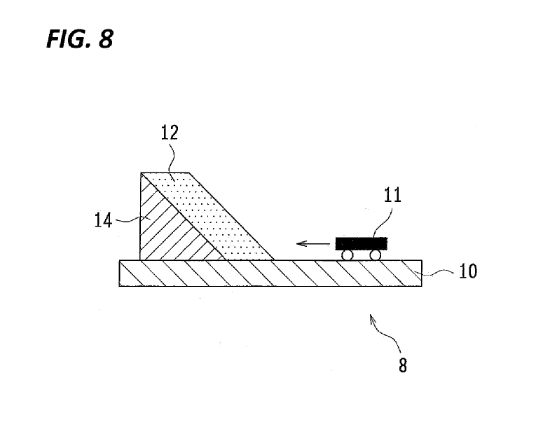

FIG. 8 is a schematic sectional view illustrating a light emitting device according to a sixth exemplary embodiment. As illustrated in FIG. 8, in a light emitting device 8 of the sixth exemplary embodiment, a semiconductor light emitting element 11 is mounted on a substrate 10, a reflection member 14 having an inner side surface inclined in relation to the substrate 10 is disposed at a location spaced apart from the semiconductor light emitting element 11, and a wavelength conversion member 12 is formed on the inclined surface of the reflection member 14. In the present exemplary embodiment, as for the semiconductor light emitting element 11, an edge emitting type element is used, and for example, a super luminescent diode (SLD) or a semiconductor laser (LD) may be employed.

A short-wavelength visible light emitted from the edge emitting type semiconductor light emitting element 11 is emitted with a directivity in the direction indicated by the arrow in the drawing to reach the wavelength conversion member 12. A part of the short-wavelength visible light is subjected to wavelength conversion by the wavelength conversion member 12, while the other part passes through the wavelength conversion member 12, and is scattered and reflected by the reflection member 14 to be incident on the wavelength conversion member 12 again. Accordingly, it is possible to satisfactorily reflect the short-wavelength visible light by the reflection member 14 so that the efficiency of white light emission from the wavelength conversion member 12 may be improved, thereby improving the light flux and the brightness of the light emitting device 8.

### Seventh Exemplary Embodiment

In the examples of the first to fifth exemplary embodiments, the entire periphery of the semiconductor light emitting element 11 is surrounded by the reflection member 14. However, in the present disclosure, a band gap of light scattering particles is 3.4 eV or more, and a refractive index difference between a dispersion medium and the light scattering particles is 0.3 or more. Thus, although the semiconductor light emitting element 11 emits a short-wavelength visible light with a peak wavelength ranging from 395 nm to 410 nm, the quantity of a light absorbed by the light scattering particles may be suppressed, and the light may be satisfactorily scattered by the light scattering particles, thereby improving the reflectivity of the reflection member 14.

Accordingly, the entire periphery of the semiconductor light emitting element 11 and the wavelength conversion member 12 may not be necessary surrounded by the reflection member 14. Only when the reflection member 14 is formed on at least a part of the periphery of the semiconductor light emitting element 11 and the wavelength conversion member 12, it is possible to satisfactorily scatter and reflect the short-wavelength visible light in the reflection member 14.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A light emitting device comprising:
a semiconductor light emitting element having a peak wavelength ranging from 395 nm to 410 nm; and
a reflection member including light scattering particles dispersed in a dispersion medium,
wherein the light scattering particles are made of a material having a band gap of 3.4 eV or more, and
a refractive index of the light scattering particles is larger than a refractive index of the dispersion medium by 0.3 or more.

2. The light emitting device of claim 1, wherein the semiconductor light emitting element has a 1 percentile value ranging from 365 nm to 383 nm in emission integrated intensity.

3. The light emitting device of claim 1, wherein the reflection member surrounds a periphery of the semiconductor light emitting element and is formed in a width ranging from 0.2 mm to 2.0 mm.

4. The light emitting device of claim 2, wherein the reflection member surrounds a periphery of the semiconductor light emitting element and is formed in a width ranging from 0.2 mm to 2.0 mm.

5. The light emitting device of claim 1, further comprising:
a wavelength conversion member that is excited by a light from the semiconductor light emitting element to emit a light with a different wavelength,
wherein the wavelength conversion member is formed on the semiconductor light emitting element in a thickness ranging from 50 nm to 500 nm, and
the reflection member is formed on at least a part of the periphery of the semiconductor light emitting element and the wavelength conversion member.

6. The light emitting device of claim 2, further comprising:
a wavelength conversion member that is excited by a light from the semiconductor light emitting element to emit a light with a different wavelength,
wherein the wavelength conversion member is formed on the semiconductor light emitting element in a thickness ranging from 50 nm to 500 nm, and
the reflection member is formed on at least a part of the periphery of the semiconductor light emitting element and the wavelength conversion member.

7. The light emitting device of claim 3, further comprising:
a wavelength conversion member that is excited by a light from the semiconductor light emitting element to emit a light with a different wavelength,
wherein the wavelength conversion member is formed on the semiconductor light emitting element in a thickness ranging from 50 nm to 500 nm, and
the reflection member is formed on at least a part of the periphery of the semiconductor light emitting element and the wavelength conversion member.

8. The light emitting device of claim 4, further comprising:
a wavelength conversion member that is excited by a light from the semiconductor light emitting element to emit a light with a different wavelength,
wherein the wavelength conversion member is formed on the semiconductor light emitting element in a thickness ranging from 50 nm to 500 nm, and
the reflection member is formed on at least a part of the periphery of the semiconductor light emitting element and the wavelength conversion member.

9. The light emitting device of claim 1, wherein the light scattering particles are made of at least one of Nb₂O₅ and Ta₂O₅.

10. The light emitting device of claim 2, wherein the light scattering particles are made of at least one of Nb₂O₅ and Ta₂O₅.

11. The light emitting device of claim 3, wherein the light scattering particles are made of at least one of Nb₂O₅ and Ta₂O₅.

12. The light emitting device of claim 4, wherein the light scattering particles are made of at least one of Nb₂O₅ and Ta₂O₅.

13. The light emitting device of claim 5, wherein the light scattering particles are made of at least one of Nb₂O₅ and Ta₂O₅.

14. The light emitting device of claim 6, wherein the light scattering particles are made of at least one of Nb₂O₅ and Ta₂O₅.

15. The light emitting device of claim 7, wherein the light scattering particles are made of at least one of Nb₂O₅ and Ta₂O₅.

16. The light emitting device of claim 8, wherein the light scattering particles are made of at least one of Nb₂O₅ and Ta₂O₅.
